(19) United States
(12) Patent Application Publication
(10) Pub. No.: US 2011/0080245 A1
(43) Pub. Date: Apr. 7, 2011

(54) MULTILAYER CIRCUIT BOARD

(76) Inventors: Tsuneo Suzuki, Monchweiler (DE); Rolf Dupper, Villingen (DE)

(21) Appl. No.: 12/889,582

(22) Filed: Sep. 24, 2010

(30) Foreign Application Priority Data
Sep. 24, 2009 (EP) 09 171164.8

(51) Int. Cl. H01F 5/00; H05K 1/11; H05K 3/10; B23K 1/002

(52) U.S. Cl. 336/200; 174/263; 29/846

(57) ABSTRACT

A multilayer circuit board includes a first dielectric layer, a second dielectric layer, a first conductor path, a second conductor path and a soldered joint. The first dielectric layer has a first side and a second side. The second dielectric layer has a first side and a second side, where the first side of the second dielectric layer facing towards the first side of the first dielectric layer. The first conductor path is disposed on the first side of the first dielectric layer. The second conductor path is disposed on the first side of the second dielectric layer. The soldered joint is disposed between the first dielectric layer and the second dielectric layer, where the soldered joint electrically connects the first conductor path to the second conductor path. The first dielectric layer extends continuously through an area surrounding the soldered joint.

### CLAIM OF PRIORITY

This patent application claims priority from EP Patent Application No. 09 171 164.8 filed Sep. 24, 2009, which is hereby incorporated by reference in its entirety.

### FIELD OF TECHNOLOGY

The invention relates to a multilayer circuit board and a method for producing a multilayer circuit board.

### RELATED ART

A typical multilayer circuit board includes a plurality of electric layers. The electrical layers can include a plurality of interior electrical layers disposed between two exterior electrical layers. The interior electrical layers can be connected by an electrical connection such as a via. Disadvantageously, vias can waste space in at least one of the exterior electrical layers. In addition, such an electrical connection increases the weight of the circuit board.

There is a need for an improved multilayered circuit board.

### SUMMARY OF THE INVENTION

According to a first aspect of the invention, a multilayer circuit board includes a first dielectric layer, a second dielectric layer, a first conductor path, a second conductor path and a soldered joint. The first dielectric layer has a first side and a second side. The second dielectric layer has a first side and a second side, where the first side of the second dielectric layer faces towards the first side of the first dielectric layer. The first conductor path is disposed on the first side of the first dielectric layer. The second conductor path is disposed on the first side of the second dielectric layer. The soldered joint is disposed between the first dielectric layer and the second dielectric layer, where the soldered joint electrically connects the first conductor path to the second conductor path. The first dielectric layer extends continuously through an area surrounding the soldered joint.

According to a second aspect of the invention, an optical reader includes a lens and a multilayer circuit board mechanically connected to the lens. The multilayer circuit board includes a first dielectric layer, a second dielectric layer, a first conductor path, a second conductor path and a soldered joint. The first dielectric layer has a first side and a second side. The second dielectric layer has a first side and a second side, where the first side of the second dielectric layer faces towards the first side of the first dielectric layer. The first conductor path is disposed on the first side of the first dielectric layer. The second conductor path is disposed on the first side of the second dielectric layer. The soldered joint is disposed between the first dielectric layer and the second dielectric layer, where the soldered joint electrically connects the first conductor path to the second conductor path. The first dielectric layer extends continuously through an area surrounding the soldered joint.

According to a third aspect of the invention, a method for producing a multilayer circuit board includes providing a first dielectric layer having a first side and a second side, and a first conductor path disposed on the first side of the first dielectric layer; providing a second dielectric layer having a first side and a second side, and a second conductor path disposed on the first side of the second dielectric layer; arranging the first dielectric layer and the second dielectric layer such that the first side of the second dielectric layer faces the first side of the first dielectric layer; and forming an electrical connection between the first conductor path and the second conductor path using induction soldering.

### DESCRIPTION OF THE DRAWINGS

The invention can be better understood with reference to the following drawings and description. Components in the figures are not necessarily drawn to scale. Instead emphasis is placed upon illustrating the principles of the invention. Moreover, in the figures, like reference numerals designate identical or equivalent elements. In the drawings:

FIG. 1 is a partial cross-sectional illustration of a prior art multilayer circuit board;

FIGS. 2 to 4 are partial cross-sectional illustrations of a multilayered circuit board at various stages during the manufacturing process;

FIG. 5 is a partial cross-sectional illustration of an embodiment of a multilayer circuit board that includes one or more electric components connected to its exterior electrical layers proximate an electrical connection between two interior electric layers;

FIG. 6 is a perspective illustration of the electric layers of one embodiment of a multilayer circuit board; and

FIG. 7 is a perspective illustration of a lens adjusting unit that includes a multilayer circuit board mechanically joined to a lens.

### DETAILED DESCRIPTION OF THE INVENTION

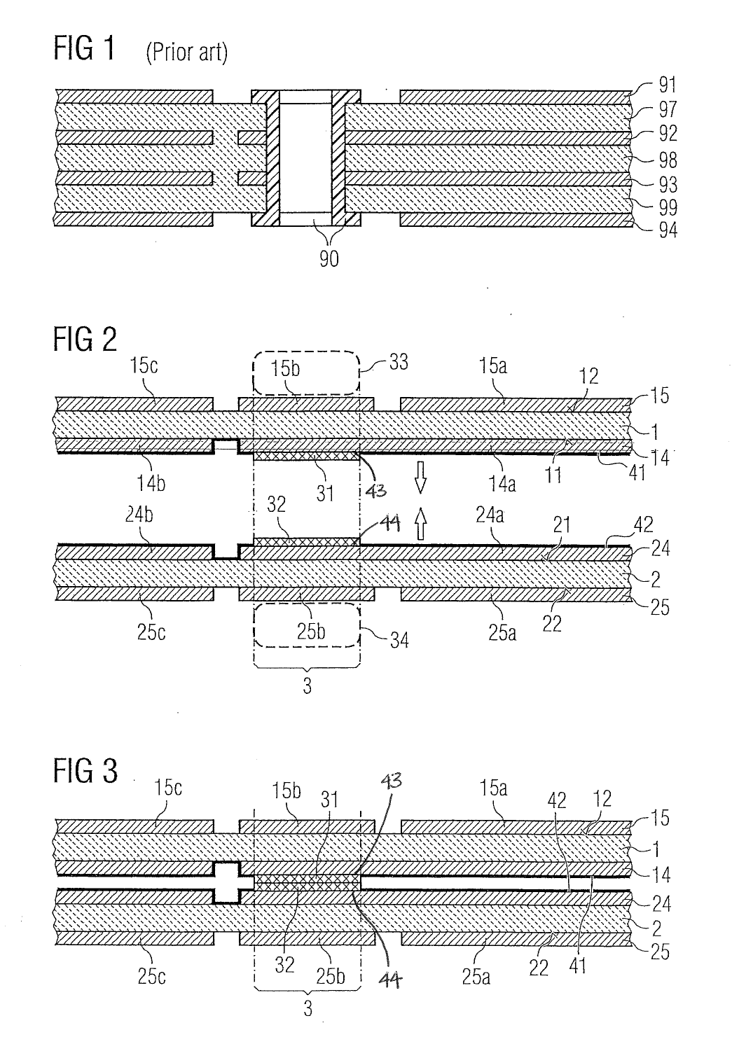

FIG. 1 is a partial cross-sectional illustration of a prior art multi-layered that includes four electric layers 91-94. A dielectric layer 97, 98, 99 is respectively disposed between the adjacent electric layers 91-94. The electric layers 91 and 94 are the outermost of the electric layers and, therefore, designated as exterior electric layers. The electric layers 92 and 93 are arranged between the exterior electric layers 91 and 94 and, therefore, designated as interior electric layers.

A via 90 extends through the multilayer circuit board, and is used to electrically connect the interior electric layers 92 and 93. However, the via 90 takes away valuable surface area from both the interior layers 92 and 93 and the exterior layers 91 and 94. The via 90 can also increase the weight of the multilayer circuit board. The increased weight may be disadvantageous in applications where the multilayer circuit board is moved, in particular accelerated and/or decelerated.

FIGS. 2 to 4 are partial cross-sectional illustrations of a multilayered circuit board at various stages during the manufacturing process. Referring to FIG. 2, a flat first dielectric layer 1 is shown having a first side 11 and a second side 12, and a flat second dielectric layer 2 is shown having a first side 21 and a second side 22. The first side 21 of the second dielectric layer 2 faces towards the first side 11 of the first dielectric layer 1. A first conductor path 14a is arranged on the first side 11 of the first dielectric layer 1. A second conductor path 24a is arranged on the first side 21 of the second dielectric layer 2.

The first conductor path 14a is formed in an interior metallization layer 14 disposed on the first side 11 of the first dielectric layer 1. The second conductor path 24a is formed in an interior metallization layer 24 disposed on the first side 21 of the second dielectric layer 2. The first and the second interior metallization layers 14, 24 may be disposed between optional first and second outer metallization layers 15, 25. The multilayer circuit board may also include additional interior metallization layers (not shown). Each of the dielectric layers 1, 2 may be configured as a stiff plate, or a flexible foil. In order to form a flexible multilayer circuit board, for example, the dielectric layers 1 and 2 may be configured as flexible foils.

The first and/or the second interior metallization layers 14 and 24 may each include one or more additional conductor paths 14b and 24b, respectively. The first outer metallization layer 15 may be arranged on the second side 12 of the first dielectric layer 1. The second outer metallization layer 25 may be arranged on the second side 22 of the second dielectric layer 2. The first and the second outer metallization layers 12, 25 may be formed continuously, or as shown in FIG. 2 comprise two or more conductive paths 15a, 15b, 15c and 25a, 25b, 25c, respectively.

Referring to FIGS. 2 and 3, the first dielectric layer 1 and the second dielectric layer 2 are arranged such that the first side 21 of the second dielectric layer 2 faces the first side 11 of the first dielectric layer 1. In a predefined lateral area 3 where the electrical connection is to be produced, solder 31, 32 is positioned between the first conductor path 14a and the second conductor path 24a. The solder 31, 32, for example, may be applied onto one or both of the first and the second conductor paths 14a and 24a within the predefined lateral area 3. The predefined lateral area 3 includes sections of the first and second conductor paths 14a and 24a where the first and second conductor paths 14a and 24a are to be electrically connected by the solder 31, 32. The predefined lateral area 3 also includes a spatial area 33 adjacent the second side 12 of the first dielectric layer 1 and a spatial area 34 adjacent the second side 22 of the second dielectric layer 2. The spatial areas 33 and 34 are opposite the predefined lateral area 3 where the electrical connection between the first and the second conductor path 14a and 24a is to be produced.

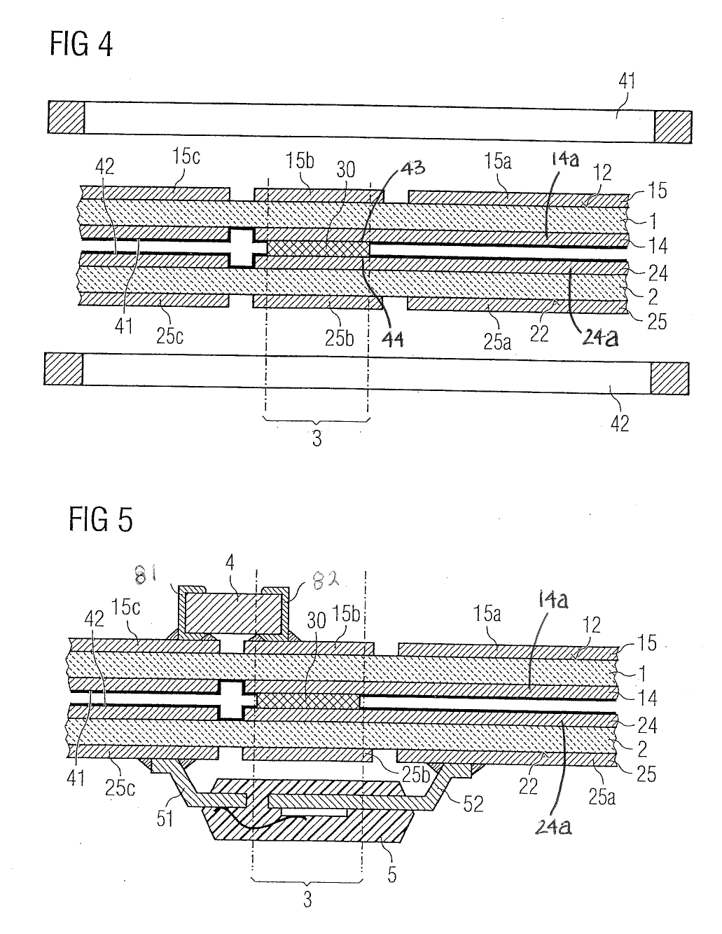

Referring to FIGS. 3 and 4, the solder 31 and/or 32 is melted using induction soldering such that a soldered joint 30 is formed that extends continuously from the first conductor path 14a to the second conductor path 24a. The soldered joint 30 includes the solder 31 and/or 32. The induction soldering is performed by arranging the predefined lateral area 3 and the solder 31 and/or 32 in the sphere of an alternating electromagnetic field. The alternating electromagnetic field is generated by at least one induction coil supplied with an alternating electrical current. During the soldering process, the first and the second dielectric layers 1 and 2 may be pressed together such that (i) the solder 31 arranged on the first conductor path 14a contacts the second conductor path 24a or the solder 32 arranged on the second conductor path 24a, and/or (ii) the solder 32 arranged on the second conductor path 24a contacts the first conductor path 14a or the solder 31 arranged on the first conductor path 14a.

In the specific embodiment shown in FIG. 4, the predefined lateral area 3 and the solder 31, 32 (see FIG. 3) are arranged between two induction coils 41 and 42. The induction coils 41 and 42 are electrically coupled in order to generate a homogeneous alternating electromagnetic field. A single induction coil, however, may be used instead of the two induction coils 41, 42 shown in FIG. 4.

Referring to FIG. 5, the electrical connection between the first and the second conductor paths 14a and 24a is formed by the solder joint 30, rather than a via as shown in FIG. 1. Advantageously, the first and/or second dielectric layers 1 and 2 may extend continuously through the predefined lateral area 3 of the soldered joint 30. Since a via is not required for forming the electrical connection between the first conductor path 14a and the second conductor path 24a, the space in the predefined lateral area 3 on the second side 12 of the first dielectric layer 1, and on the second side 22 of the second dielectric layer 2 may be used for mounting, for example, electrical or other components 4, 5 on the multilayer circuit board. In other words, at least a part of a first component 4 may be mounted to the second side 12 of the first dielectric layer 1 and/or at least a part of a second component 5 may be mounted to the second side 22 of the second dielectric layer 2 in the predefined area 3. In one embodiment, the component 4 is an SMD resistor having leads 81 and 82 which are soldered to the conductive paths 15c and 15b in the metallization layer 15. In another embodiment, the component 5 is a semiconductor circuit having leads 51 and 52 which are soldered to the conductive paths 25c and 25a in the metallization layer 25. Alternatively, the conductive paths 15b and 25b can remain free of connections in the spatial areas 33 and/or 34 as shown in FIG. 4.

Dielectric films 41 and 42 (see FIGS. 2 to 5) may be disposed on the opposite side of the respective dielectric layers 1 and 2. The dielectric films 41, 42 may be selectively removed to foam openings 43, 44 in the predefined lateral area 3 in order to locate the soldered connection 30 on at least one of the interior metal layers 14, 24. The solder 31, 32 may be respectively applied in the openings 43, 44 onto the first conductive path 14a and/or onto the second conductive path 24a. Due to the dielectric films 41, 42, unintentional short circuits to and between adjacent conductor paths 14b, 24b caused by deliquescing solder 31, 32 may be avoided.

Alternative to openings produced in a continuous dielectric film 41, 42, the dielectric films 41 and/or 42 may be applied onto the first conductive path 14a and/or onto the second conductive path 24a selectively on the surface areas of the metallizations 14 and 24, respectively, only which shall remain sealed by the respective film 41, 42. For example, the material of the dielectric film 41, 42 may be printed onto the respective conductive path 14a, 24a in the same manner as an inkjet printer prints color onto a sheet of paper. In particular, a dielectric film 41, 42 may be a layer of protective lacquer.

The multilayer circuit board may include a plurality of the soldered connections 30 between various interior metallization layers. The soldered connections 30 may be simultaneously induction soldered using the same electromagnetic field generated by the at least one induction coil 41, 42.

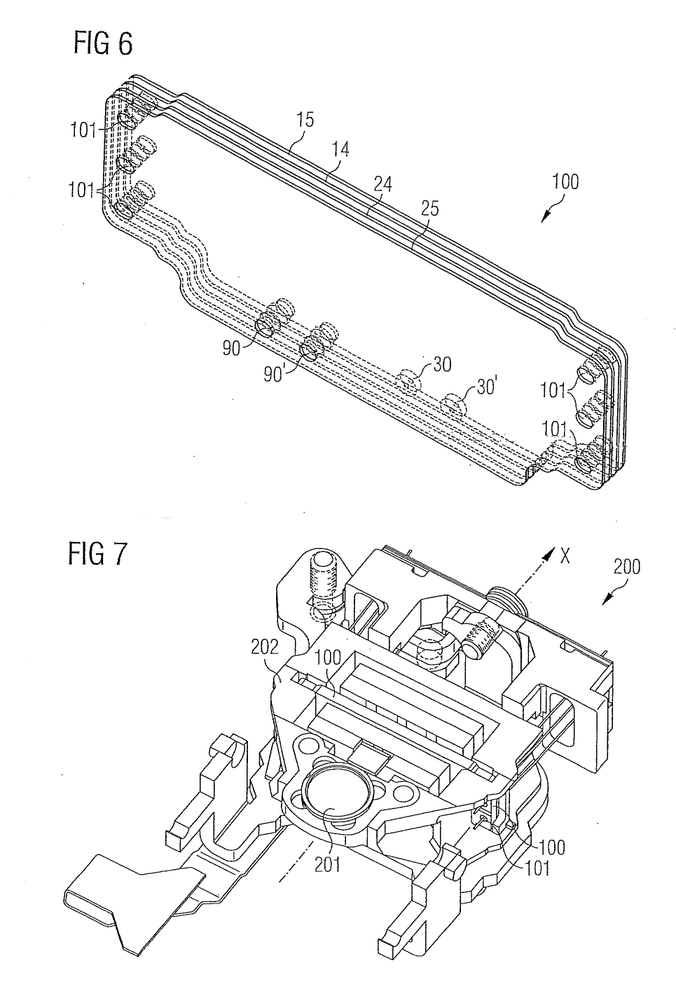

Referring to FIG. 6, the metallization layers 15, 14, 24 and 25 of one embodiment of the multilayer circuit board 100 are shown. In order to simplify the figure, however, intermediate dielectric layers between the metallization layers are not shown. The board 100 includes soldered joints 30, 30′ produced as described above with reference to FIGS. 2 to 5. The soldered joints 30, 30′ are shown by broken lines because they are covered by the exterior metallization layer 25 and, therefore, are invisible.

In addition, the board 100 may include one or more vias 90, 90′ similar to the via shown FIG. 1. The board 100 may also include one or more assembly openings 101. Each assembly opening 101 extends through the board 100 and may be used for mounting the board 100.

Referring to FIG. 7, a lens adjusting unit includes the multilayer circuit board 100 and a lens 201. The lens 201 is mechanically joined with the multilayer circuit board 100 by a mounting frame 202. At least two interior metallizations of the multilayer circuit board 100 include a turn of a coil. Each of the turns is formed as conductive path which is formed by structurizing the respective interior metallization. In order to produce a coil having two or more turns, the turns formed in adjacent metallizations are electrically connected by electrical joints configured similar to the soldered joint 30 (see FIGS. 2-5). The coil is positioned in a magnetic field of a permanent magnet or of an electromagnet. By supplying a defined electric current to the coil, the multilayer circuit board 100 together with the mounting frame 202 and the lens 201 may be moved back and forth in a direction x which may run substantially perpendicular to the multilayer circuit board 100.

Due to the absence or the reduced number of vias in the multilayer circuit board 100, the weight and, therefore, the inertial mass of the board 100 are reduced. As a result, the time used for adjusting the lens 201 together with the board 100 and the mounting frame 202 is also reduced.

The multilayer circuit board may be used in other technical fields such as in mobile computers, mobile phones, portable audio players, optical scanner units, optical drives, mobile navigation systems, personal data assistants, etc.

While various embodiments of the invention have been described, it will be apparent to those of ordinary skill in the art that other embodiments and implementations are possible that are within the scope of this invention. Accordingly, the invention is not restricted except in light of the attached claims and their equivalents.

What is claimed is:

1. A multilayer circuit board, comprising
a first dielectric layer having a first side and a second side;
a second dielectric layer having a first side and a second side, the first side of the second dielectric layer facing towards the first side of the first dielectric layer;
a first conductor path disposed on the first side of the first dielectric layer;
a second conductor path disposed on the first side of the second dielectric layer; and
a soldered joint disposed between the first dielectric layer and the second dielectric layer, where the soldered joint electrically connects the first conductor path to the second conductor path;
where the first dielectric layer extends continuously through an area surrounding the soldered joint.

2. The multilayer circuit board of claim 1, where the second dielectric layer extends continuously through the area surrounding the soldered joint.

3. The multilayer circuit board of claim 1, where the first conductor path and the second conductor path form an electric coil.

4. The multilayer circuit board of claim 1, where the solder joint includes solder that extends continuously from the first conductor path to the second conductor path.

5. The multilayer circuit board of claim 1, where at least one of
a first electric component is mounted to the second side of the first dielectric layer in the area surrounding the solder joint; and
a second electric component is mounted to the second side of the second dielectric layer in the area surrounding the solder joint.

6. The multilayer circuit board of claim 1, where a first metallization is disposed on the second side of the first dielectric layer;

7. A method for producing a multilayer circuit board, comprising:
providing a first dielectric layer having a first side and a second side, and a first conductor path disposed on the first side of the first dielectric layer;
providing a second dielectric layer having a first side and a second side, and a second conductor path disposed on the first side of the second dielectric layer;
arranging the first dielectric layer and the second dielectric layer such that the first side of the second dielectric layer faces the first side of the first dielectric layer; and
forming an electrical connection between the first conductor path and the second conductor path using induction soldering.

8. The method of claim 7, further comprising:
predefining a first surface section on the first conductive path; and
predefining a second surface section on the second conductive path;
where the electrical connection is formed between the first surface section and the second surface section.

9. The method of claim 8, further comprising arranging the first surface section opposite to the second surface section.

10. The method of claim 8, further comprising disposing solder between the first surface section and the second surface section.

11. The method of claim 8, further comprising applying solder to at least one of the first surface section and the second surface section.

12. The method of claim 8, further comprising applying solder to the first surface section and the second surface section, where the solder on the first and the second surface sections is fused together during the step of induction soldering.

13. The method of claim 7, where at least one of the first dielectric layer and the second dielectric layer extends continuously through an area surrounding the electrical connection.

14. The method of claims 13, where in the area surrounding the solder joint at least one of
a first electric component is mounted to the second side of the first dielectric layer; and
a second electric component is mounted to the second side of the second dielectric layer.
